(19) United States
(12) Patent Application Publication
(10) Pub. No.: US 2011/0233685 A1
(43) Pub. Date: Sep. 29, 2011

(54) SEMICONDUCTOR INTEGRATED CIRCUIT

(75) Inventors: Takayuki Ito, Oita-shi (JP); Kenichi Yoshino, Oita-shi (JP); Tomoya Sanuki, Oita-shi (JP); Hiroshi Ohno, Yokohama-shi (JP)

(73) Assignee: KABUSHIKI KAISHA TOSHIBA, Tokyo (JP)

(21) Appl. No.: 13/051,533

(22) Filed: Mar. 18, 2011

(30) Foreign Application Priority Data
Mar. 26, 2010 (JP) P2010-073713

(51) Int. Cl. H01L 27/088; H01L 21/336

(52) U.S. Cl. 257/390; 438/301; 257/E27.06; 257/E21.409

(57) ABSTRACT

According to embodiments, there is provided a semiconductor device, including: a first area including plural transistors formed therein; and a second area including plural dummy transistors formed therein, the second area surrounding the first area, wherein a pitch of the dummy transistors is equal to or less than a central wavelength of a light used to form the transistors.

### CROSS-REFERENCE TO RELATED APPLICATIONS

This application claims priority from Japanese Patent Application No. 2010-073713 filed on Mar. 26, 2010, the entire contents of which are incorporated herein by reference.

### FIELD

Embodiments described herein relate generally to a semiconductor device.

### BACKGROUND

In order to miniaturize elements in semiconductor devices, it is important to form impurity diffusion layers to be shallow while being low resistance. For forming a shallow/low-resistance impurity diffusion layer, e.g., JP-2007-123844-A proposes an ultrashort-time annealing method using a flash lamp or a laser, instead of an ordinary rapid thermal anneal (RTA) method.

When such ultrashort-time annealing is performed to anneal a semiconductor substrate, variation in effective-annealing-temperature may occur between a area with densely-formed semiconductor elements, and another area with sparsely-formed semiconductor elements, on the semiconductor substrate. Thus, characteristic variation may occur between a transistor in the dense area and a transistor in the sparse area.

In order to reduce such annealing-temperature variation, for example, JP-A-2009-130243-A proposes to form a light-absorbing film containing carbon on a surface of a semiconductor substrate during annealing. However, such light-absorbing film containing carbon should be formed at high temperature to obtain sufficient light absorption characteristic. Such high-temperature formation of a light-absorbing film will promote the abnormal diffusion of dopants in the impurity diffusion layer and the growth of secondary defects. Thus, it is difficult to form a shallow/low-resistance impurity diffusion layer. In addition, when the light-absorbing film is used, the step of peeling the light-absorbing film is further needed after the step of annealing. Thus, the number of steps and the cost may be increased.

Other than the method using the light-receiving film, for example, JP-A-2008-211214-A proposes to uniformize the density of semiconductor elements by arranging dummy transistors around a area in which transistors are formed. However, JP-A-2008-211214-A may insufficiently reduce the annealing temperature variation.

### BRIEF DESCRIPTION OF DRAWINGS

FIG. 1 is a plan view illustrating a semiconductor device according to Embodiment 1.

FIG. 2 is a cross-sectional view illustrating the semiconductor device according to Embodiment 1.

FIGS. 3A to 3G are cross-sectional views illustrating a process of manufacturing a transistor formed in a first area according to Embodiment 1.

FIG. 4 is a graph illustrating the wavelength spectra of flash lamp light according to Embodiment 1.

FIG. 5 illustrates a temperature distribution on a semiconductor surface when performing flash lamp annealing on a first area and a second area of the semiconductor device according to Embodiment 1.

FIG. 6 is a plan view illustrating a semiconductor device according to a comparison example.

FIG. 7 illustrates a temperature distribution on a semiconductor surface when performing flash lamp annealing on a first area and a second area of the semiconductor device according to a comparison example.

FIG. 8 illustrates the relation between a dummy-transistor pattern (i.e., a ratio of the width d of each dummy transistor to the pitch p of dummy transistors) and a thermal emissivity.

FIG. 9 is a plan view illustrating a semiconductor device according to Embodiment 2.

FIG. 10 is a cross-sectional view illustrating the semiconductor device according to Embodiment 2.

FIG. 11 illustrates the temperature dependence of a thermal diffusion length when annealing a silicon substrate with flash lamp light.

FIG. 12 illustrates a temperature distribution on a semiconductor surface when performing flash lamp annealing on the semiconductor device according to Embodiment 2.

FIG. 13 is a plan view illustrating a semiconductor device according to a comparison example.

FIG. 14 illustrates a temperature distribution on a semiconductor surface when performing flash lamp annealing on the semiconductor device according to the comparison example.

FIG. 15 is a cross-sectional view illustrating a step of manufacturing a semiconductor device according to Embodiment 3.

FIG. 16 illustrates the temperature dependence of an annealing temperature versus the power of a flash lamp in the cases where the implantation of germanium (Ge) is performed, and where the implantation of Ge is not performed.

FIG. 17 is a cross-sectional view illustrating a step of manufacturing a semiconductor device according to Embodiment 4.

### DETAILED DESCRIPTION

According to embodiments, there is provided a semiconductor device, including: a first area including plural transistors formed therein; and a second area including plural dummy transistors formed therein, the second area surrounding the first area, wherein a pitch of the dummy transistors is equal to or less than a central wavelength of a light used to form the transistors.

Hereinafter, embodiments will be described with reference to the drawings.

### Embodiment 1

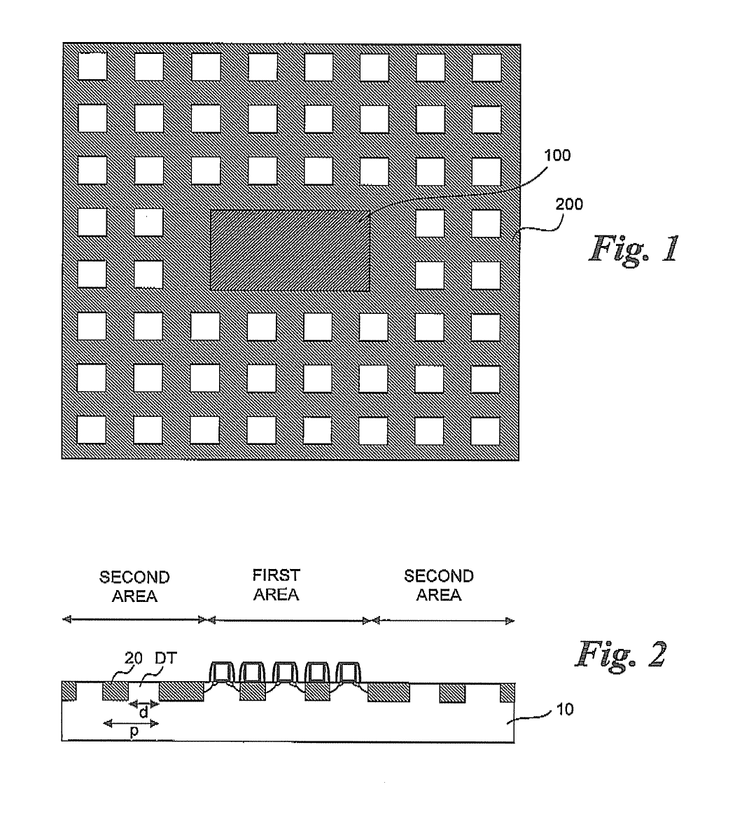

A semiconductor device according to Embodiment 1 is described hereinafter with reference to FIGS. 1 and 2. FIG. 1 is a plan view illustrating the semiconductor device according to Embodiment 1. FIG. 2 is a cross-sectional view illustrating the semiconductor device according to Embodiment 1. As illustrated in FIG. 1, the semiconductor device according to the present embodiment includes a first area 100 and a second area 200 provided on a semiconductor substrate 10. Plural transistors are formed in the first area 100. The second area 200 is arranged around the first area 100, and plural dummy transistors are formed in the second area 200.

In the first area 100, plural transistors are densely formed, as a semiconductor memory, or a logic circuit.

In the second area 200, plural dummy transistors DT are formed. As illustrated in FIGS. 1 and 2, each dummy transistor DT has an element formation region surrounded by an element isolation region 20 in every direction. The pitch p of the dummy transistors DT is defined by the distance between the edges of the element isolation regions 20 in each pair of the adjacent dummy transistors DT. The width d of each dummy transistor DT is defined by the width of the element formation region thereof. It is assumed that a flash lamp light having the central wavelength 2c is used to form plural transistors in the first area 100. In this case, the dummy transistors DT are formed such that the pitch p thereof is equal to or less than the central wavelength λc and that the width d of the dummy transistors DT is equal to or less than half the pitch p thereof. Details for forming the dummy transistors in such a manner will be described below.

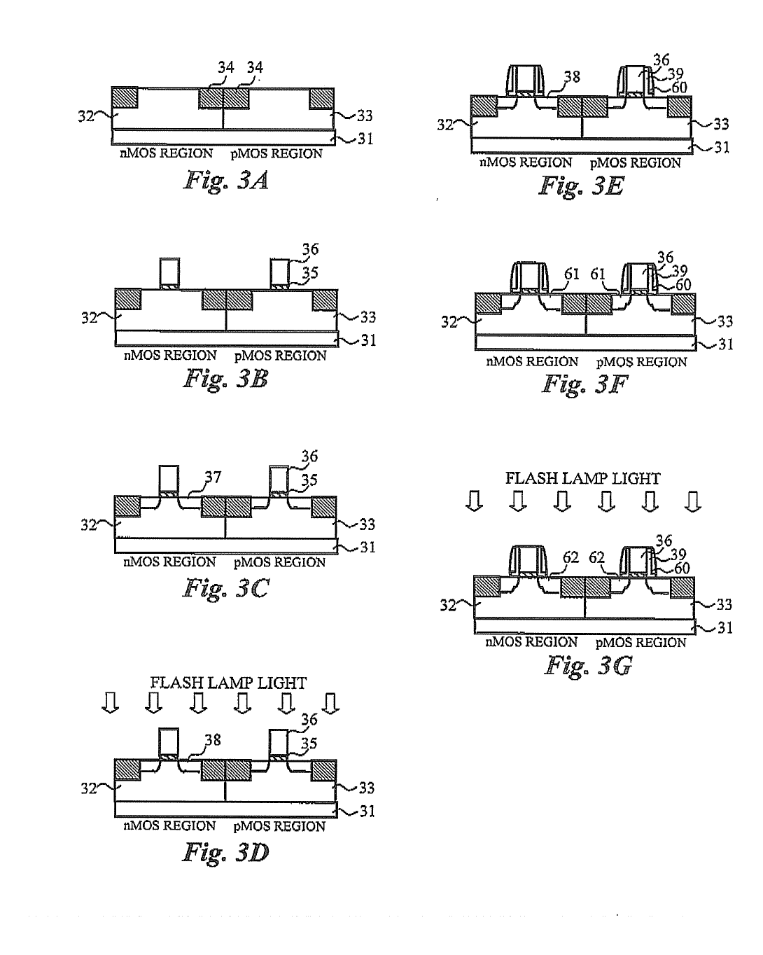

Next, a process of manufacturing transistors formed in the first area of the semiconductor device according to the present embodiment is described hereinafter with reference to FIGS. 3A to 3G. FIGS. 3A to 3G are cross-sectional views illustrating the process of manufacturing transistors formed in the first area 100 illustrated in FIGS. 1 and 2.

First, as illustrated in FIG. 3A, an element isolation region 34 is formed to define an n-MOS region and a p-MOS region. Then, a p-well layer 32 is formed in the n-MOS region, while an n-well layer 33 is formed in the p-MOS region.

Next, as illustrated in FIG. 3B, a gate insulating film 35 and a gate electrode 36 are formed on the n-MOS region and the p-MOS region of the semiconductor substrate 31, respectively.

Next, as illustrated in FIG. 3C, group-V atoms (e.g., arsenic (As) atoms) serving as n-type impurities are ion-implanted into a surface of the p-well layer 32 using the gate electrode 36 as a mask. For example, conditions for As-ion implantation are such that accelerating energy is 2 kilo-electron-volts (key), and that a dose amount is 1×10¹⁵ per square centimeters (cm⁻²). Then, group-III atoms (e.g., boron (B) atoms) serving as p-type impurities are ion-implanted into a surface of the n-well layer 33. For example, conditions for B-ion implantation are such that accelerating energy is 0.5 keV, and that a dose amount is 1×10¹⁵ cm⁻². As a result of the above two ion-implantation steps, an impurity-implanted layer 37 having a depth of about 15 nm from the surface of the semiconductor substrate 31 is formed.

Next, as illustrated in FIG. 3D, As-ions and B-ions implanted into the impurity-implanted layer 37 are taken into and substituted in lattice sites and activated by irradiating flash lamp light onto the semiconductor substrate 31. Thus, then-type active layer and the p-type active layer 38 are formed. Usually, flash lamp light is irradiated thereonto while auxiliarily heating the semiconductor substrate 31 by an auxiliary heater.

Next, as illustrated in FIG. 3E, a silicon dioxide (SiO₂) film 39, and a side wall spacer 60 configured by a silicon nitride (Si₃N₄) film are formed on each gate electrode 36 by a known method.

Next, as illustrated in FIG. 3F, group-V atoms (e.g., phosphorus (P) atoms) serving as n-type impurities are ion-implanted into the surface of the p-well layer 32, using the gate electrodes 36 and the side wall spacers 60 as masks. Then, group-III atoms (e.g., B-atoms) serving as p-type impurities are ion-implanted into the surface of the n-well layer 32. Consequently, a source-drain impurity region 61 is formed to be separated from an end part of the gate electrode 36 and to be contacted with the element isolation region 34. Through the ion implantation, associated impurity ions may be also implanted into the gate electrode 36.

Next, as illustrated in FIG. 3G, As-ions and B-ions implanted into the impurity implanted layer 37 are taken into and substituted in lattice sites and activated by irradiating flash lamp light from the surface of the semiconductor substrate 31. For example, the flash lamp light may be irradiated under the conditions that a pulse width is 1 millisecond (ms), and that irradiating energy is 30 joules (J)/cm². The P-ions and the B-ions implanted into the impurity-implanted layer 61 are taken in and substituted in lattice sides and activated by this activation heat treatment. Consequently, the n-type active layer and the p-type active layer 62 are formed between both end parts of the gate insulating film 35 and the element isolation regions 34.

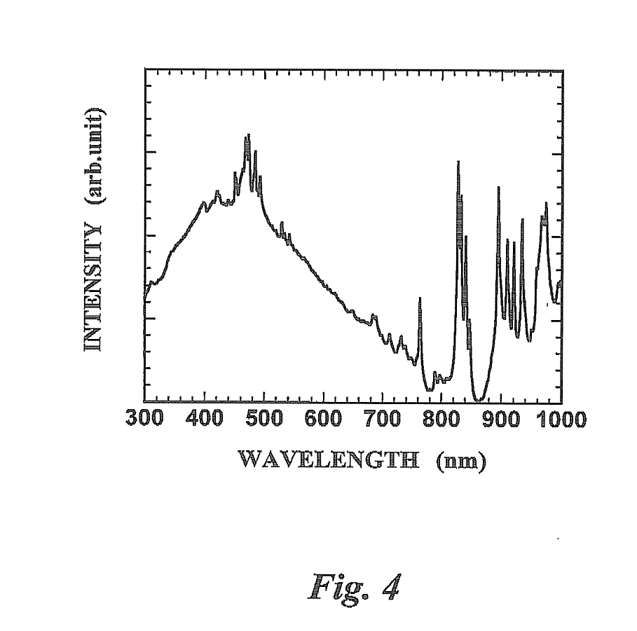

As described above, in the process of forming transistors, the annealing using flash lamp light is performed. FIG. 4 illustrates the waveform spectra of flash lamp light. When flash lamp light is irradiated onto plural transistors formed in the first area of the semiconductor device illustrated in FIGS. 1 and 2, the flash lamp light is also irradiated onto a area (i.e., the second area) arranged around the first area. Here, a semiconductor device having the first area with the densely-formed transistors and the second area with the sparsely-formed transistors is assumed, as a comparison example. If annealing using flash lamp light is performed in the comparison-example semiconductor device, an annealing-temperature variation is caused between the first area and the second area. Contrary, according to the present embodiment, as shown in FIGS. 1 and 2, when annealing using flash lamp is performed, the annealing-temperature variation between the first area and the second area can be reduced by virtue of plural dummy transistors formed in a area (i.e., the second area) arranged around the first area. The pitch p of dummy transistors DT formed in the second area is set to be equal to or less than the central wavelength 2c of the flash lamp light used when plural transistors are formed in the first area. In addition, the width d of the dummy transistors DT is set to be equal to or less than half the pitch p of the dummy transistors. Consequently, the annealing-temperature variation between the first area and the second area can be reduced.

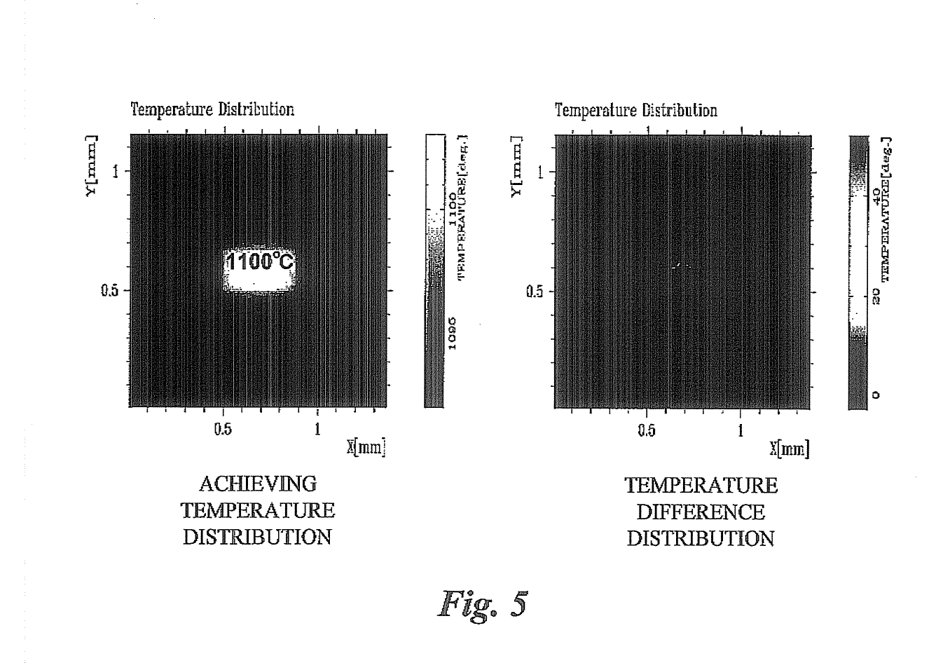

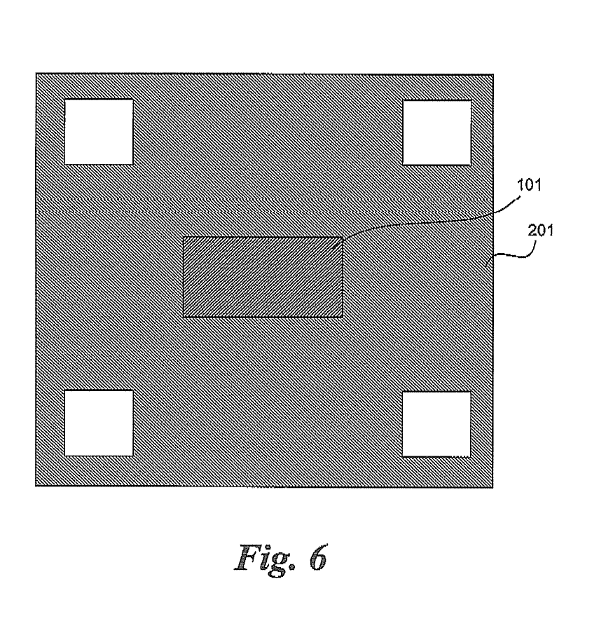

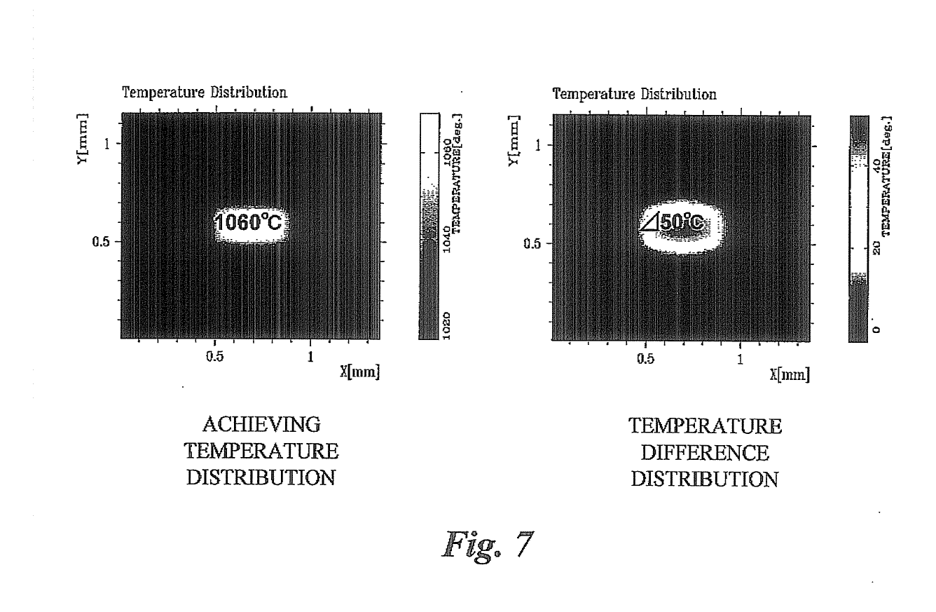

Next, advantages of the semiconductor device according to the present embodiment to a semiconductor device according to a comparison example is described hereinafter with reference to FIGS. 5, 6, and 7. FIG. 5 illustrates a simulation result of a temperature distribution on a semiconductor surface when performing flash lamp annealing on the first area and the second area of the semiconductor device according to the present embodiment shown in FIGS. 1 and 2. FIG. 6 is a plan view illustrating the semiconductor device according to the comparison example. FIG. 7 illustrates a simulation result of a temperature distribution on a semiconductor surface when performing flash lamp annealing on the first area and the second area of the semiconductor device according to the comparison example.

The semiconductor device according to the comparison example illustrated in FIG. 6 includes a first area 101 in which plural transistors are formed, and a second area 201 arranged around the first area, in which no transistors are formed.

When flash lamp annealing is performed on the comparison-example semiconductor device illustrated in FIG. 6 by setting an annealing temperature at 1000° C., the temperature of the first area 101 rises to 1060° C., while that of second area 201 rises to 1010° C., as illustrated in FIG. 7. Thus, a temperature variation of about 50° C. is caused between the first area and the second area.

On the other hand, when flash lamp annealing is performed on the embodiment semiconductor device illustrated in FIGS. 1 and 2 by setting the annealing temperature at 1000° C., the temperature of the first area 100 is about 1100° C., while that of the second area 200 is about 1095° C., as illustrated in FIG. 5. Thus, the embodiment semiconductor device can reduce the temperature variation between the first area and the second area, as compared with the comparison-example semiconductor device.

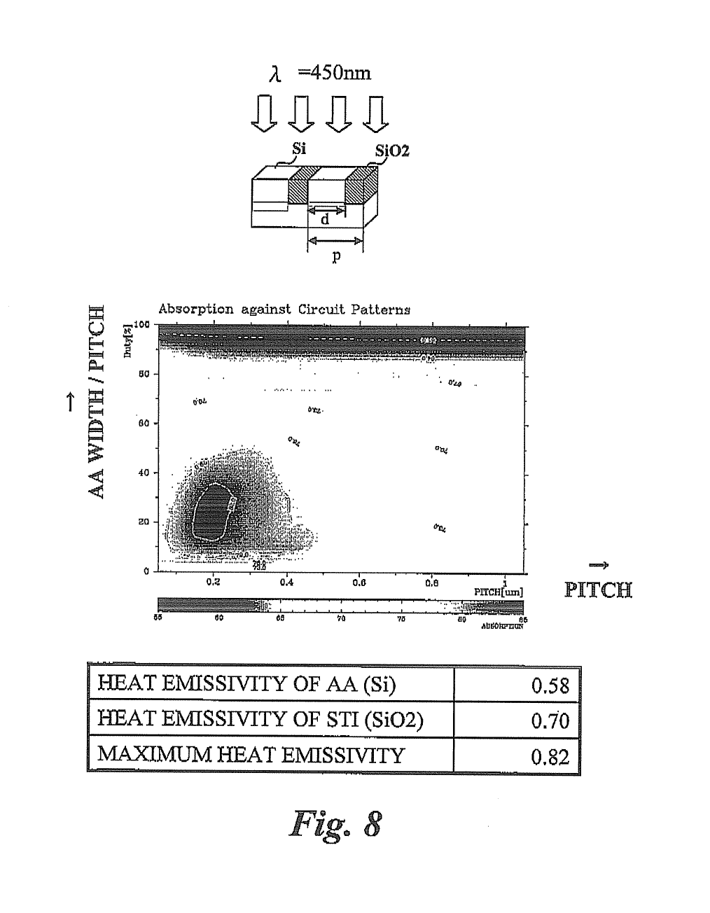

In the semiconductor device according to the present embodiment shown in FIGS. 1 and 2, while the flash lamp light having the central wavelength λc is used to form plural transistors in the first area 201, the pitch p of the dummy transistors DT formed in the second area 201 is set to be equal to or less than the central wavelength λc, and the width d of the dummy transistors DT is set to be equal to or less than half the pitch p of the dummy transistors DT. Next, details about the setting of the pitch p of the dummy transistors DT and the setting of the width d of the dummy transistors DT will be described with reference to FIG. 8. FIG. 8 illustrates the relation between a dummy-transistor pattern (i.e., a ratio of the width d of each dummy transistor to the pitch p of the dummy transistors) and the thermal emissivity of the semiconductor device when flash lamp light having a center frequency of 450 nm is irradiated to the dummy-transistor. The thermal emissivity is given as follows, using a reflectance ratio of flash lamp light impinging upon the semiconductor device, an absorption ratio of light absorbed by the semiconductor device, and a transmission ratio of light transmitted by the semiconductor device.

Thermal Emissivity=1−Reflectance Ratio=Absorption Ratio+Transmission Ratio.

As can be seen from FIG. 8, the thermal emissivity is large when the pitch (abscissa axis) of the dummy transistors is equal to or less than the central wavelength of flash lamp annealing-light. In addition, the emissivity is large (the maximum emissivity is about 0.82) when the ratio (ordinate axis) of the width d of the dummy transistors to the pitch p of the dummy transistors is less than half. Usually, the thermal emissivity of the element formation region (active area (AA)) is about 0.58, and the thermal emissivity of the element isolation region (shallow trench isolation (STI) region) is about 0.70. Accordingly, by employing the above pattern of the dummy transistors, the thermal emissivity is likely to be increased due to diffraction effects of light than estimated from each material. Thus, the emissivity of the second area can be increased so as to be comparable to the emissivity of the first area, thereby reducing the annealing temperature variation between the first area and the second area when the flash lamp annealing is performed.

Thus, the second area in which plural dummy transistors are formed is arranged around the first area in which plural transistors are densely formed. In addition, plural dummy transistors are designed to have the pattern associated with the wavelength of flash lamp light for annealing, Consequently, the annealing temperature variation between the first area and the second area can be reduced, when the flash lamp annealing is performed.

### Embodiment 2

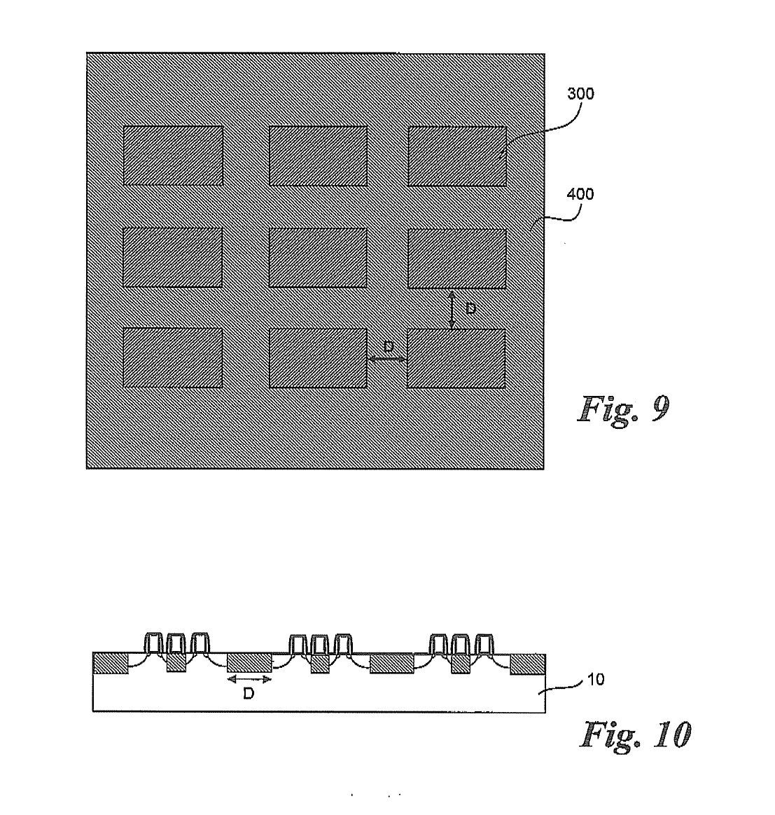

A semiconductor device according to Embodiment 2 is described hereinafter with reference to FIGS. 9 and 10. FIG. 9 is a plan view illustrating the semiconductor device according to Embodiment 2. FIG. 10 is a cross-sectional view illustrating the semiconductor device according to Embodiment 2. As illustrated in FIG. 9, the semiconductor device according to the present embodiment includes plural areas 300, and each area 300 includes plural transistors formed therein. The plural transistors in the areas 300 are formed by a process similar to that illustrated in FIGS. 3A to 3G according to Embodiment 1. The areas 300 are defined from each other by the element isolation region 400.

The element isolation region 400 among the areas 300 is formed to have the width D wider than a thermal diffusion length L due to heat given to the semiconductor substrate 10 by flash lamp light used when plural transistors are formed in each area 300. The thermal diffusion length L is given by the following equation.

$$L = \sqrt{\begin{matrix}( thermal conductivity ) / ( density ) / \\ ( specific heat ) ( annealing time )\end{matrix}}$$

where the thermal conductivity is of the semiconductor substrate 10, the density is of the silicon substrate 10, and the specific heat is of the semiconductor substrate 10.

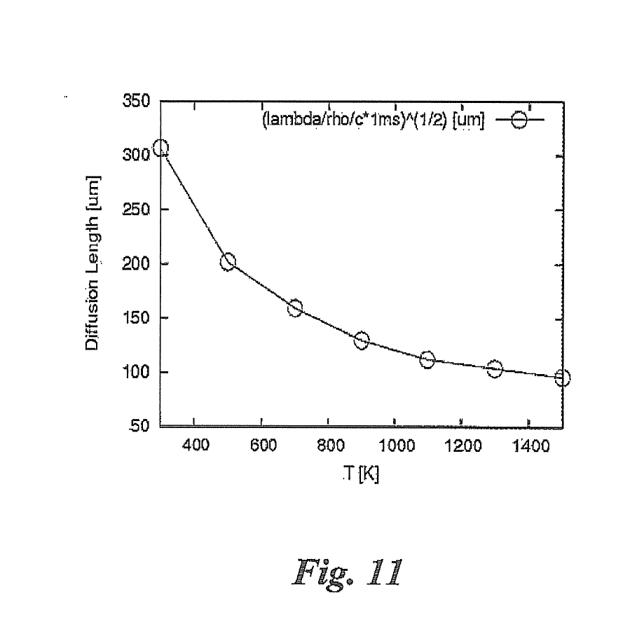

FIG. 11 illustrates the temperature dependence of the thermal diffusion length L when annealing the silicon substrate 10 with flash lamp light. The graph illustrated in FIG. 11 is obtained by the equation giving the thermal diffusion length L. The thermal diffusion length L is determined by giving the annealing temperature thereto.

Thus, when the silicon substrate 10 is annealed with flash lamp light, each area 300 can thermally be isolated by defining the areas 300 at a width D wider than the thermal diffusion length L. Consequently, the temperature of each area 300 can be restrained from rising.

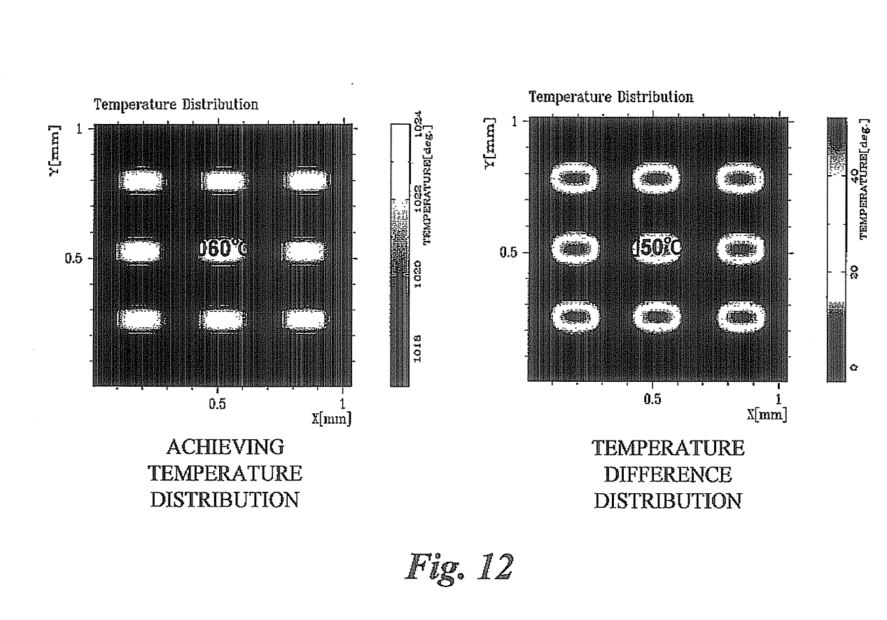

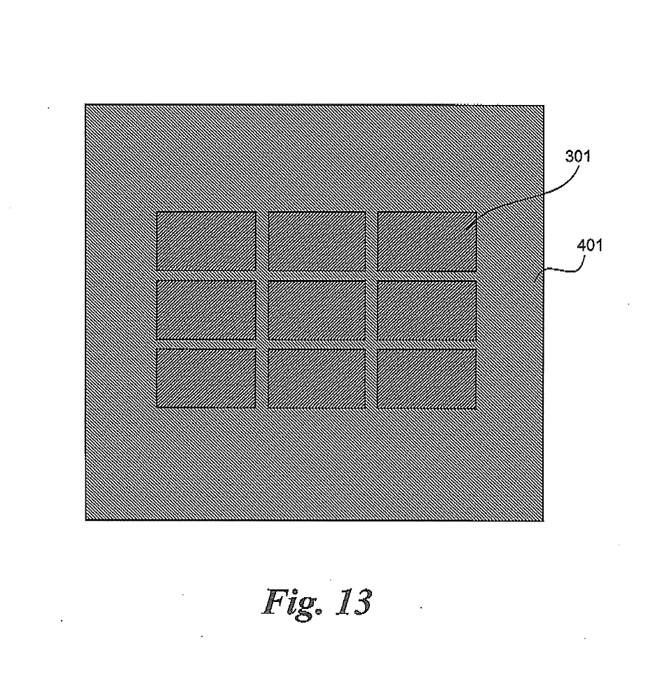

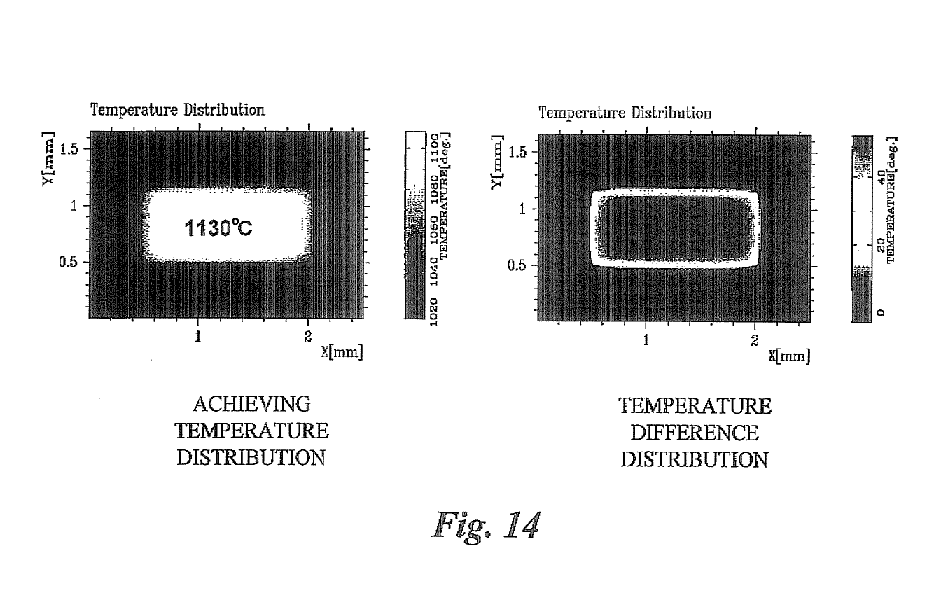

Next, advantages of the semiconductor device according to the present embodiment to a semiconductor device according to a comparison example is described hereinafter with reference to FIGS. 12, 13, and 14. FIG. 12 illustrates a simulation result of a temperature distribution on a semiconductor surface when performing flash lamp annealing on the areas 300 of the semiconductor device shown in FIGS. 9 and 10. FIG. 13 is a plan view illustrating the semiconductor device according to the comparison example. FIG. 14 illustrates a simulation result of a temperature distribution on a semiconductor surface when performing flash lamp annealing on areas 301 of the semiconductor device shown in FIG. 13.

In the comparison-example semiconductor device illustrated in FIG. 13, each area 301 in which plural transistors are formed is defined by the element isolation region 401. The element isolation region 401 is formed so that the width thereof is narrower than the above thermal diffusion length L. In the comparison example, the width of the element isolation region 401 defining each area 301 in which plural transistors are formed is determined regardless of the thermal diffusion length L. Usually, for the purpose of space-saving of the semiconductor device, the element isolation region 401 is formed to be narrow.

When flash lamp annealing is performed on the semiconductor device illustrated in FIG. 13, the temperature of each area 301 in which plural transistors are formed is increased to 1130° C. as shown in FIG. 14. Thus, the temperature difference between each area 301 and the surrounding part thereof is increased to 110° C.

On the other hand, when flash lamp annealing is performed on the embodiment semiconductor device shown in FIGS. 9 and 10, on the same conditions as those illustrated in FIG. 14, the temperature of each area 300 in which plural transistors are formed is restrained from being increased to 1060° C. In addition, the temperature difference between each area 300 and the surrounding part thereof is reduced to 50° C.

Thus, according to the present embodiment, plural areas 300, in each of which plural transistors are formed, is isolated from each other by the element isolation region 400 having a width D equal to or wider than the thermal diffusion length L. Accordingly, an effective-annealing-temperature variation at the annealing performed with the flash lamp can be reduced.

### Embodiment 3

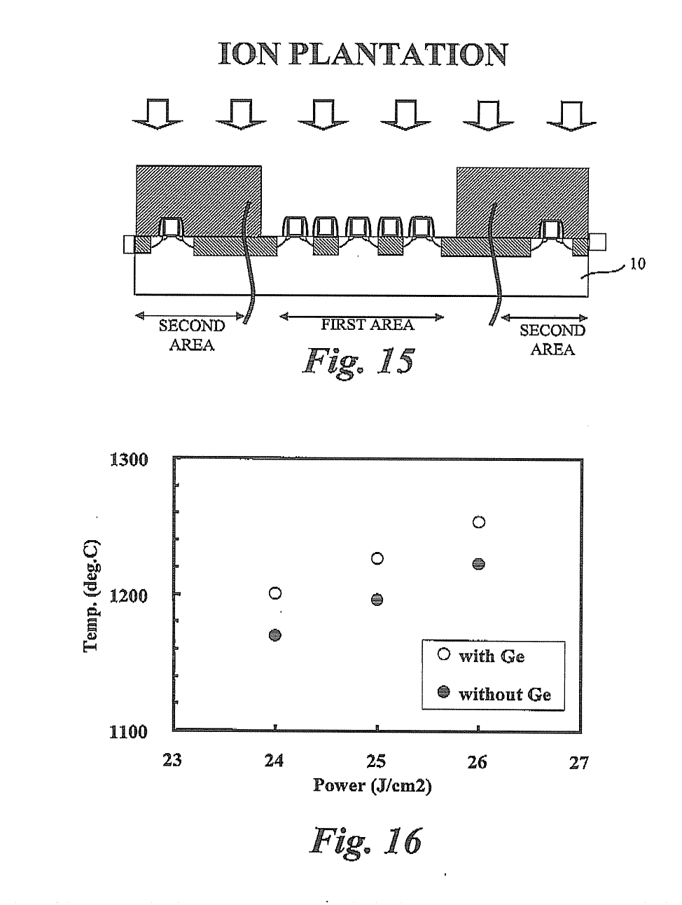

A manufacturing method for a semiconductor device according to Embodiment 3 is described hereinafter with reference to FIG. 15. FIG. 15 is a cross-sectional view illustrating a step of manufacturing the semiconductor device. In the first area of the semiconductor device, plural semiconductor elements are densely formed. In the second area of the semiconductor device, semiconductor elements are sparsely formed. As described in Embodiment 1, when annealing is performed on a area (first area) in which semiconductor elements are densely formed, and another area (second area) in which semiconductor elements are sparsely formed, with flash lamp annealing light, a annealing temperature variation is caused between the first area and the second area.

According to the present embodiment, before annealing using flash lamp light is performed, the ion-implantation of nonconductive elements (such as germanium (Ge)) into the first area is performed. At that time, the second area is covered with a mask or the like. Thus, the ion-implantation is not performed on the second area. Consequently, a gate conductor poly-silicon (GC-poly) portion of the first area can be amorphousized. Then, after the mask formed on the second area is peeled off, annealing is performed on the first area and the second area with flash lamp light. The adjustment of the thermal emissivity of flash lamp light can be performed on the first area and the second area by amorphousizing only the GC-poly portion of the first area. The annealing-temperature variation can be reduced between the first area and the second area.

FIG. 16 illustrates change in the annealing temperature, which is caused by the Ge-ion implantation. Specifically, FIG. 16 illustrates the temperature-characteristic of the annealing temperature versus the power of a flash lamp in the cases where the Ge-implantation is performed (the accelerating energy is 10 KeV, and the dose amount is 5×10¹⁴ cm⁻²), and where the Ge-implantation is not performed.

As can be seen from FIG. 16, the thermal emissivity of the surface of the GC-poly portion is reduced by the Ge-ion implantation, and the effective annealing temperature of the first area is lowered about 30° C. Accordingly, the effective annealing-temperature variation caused between the first area and the second area at the annealing can be reduced.

### Embodiment 4

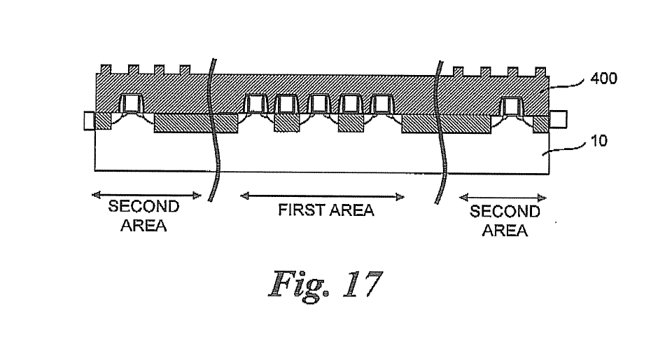

A manufacturing method for a semiconductor device according to Embodiment 4 is described hereinafter with reference to FIG. 17. FIG. 17 is a cross-sectional view illustrating a step of manufacturing the semiconductor device. In the first area of the semiconductor device, plural semiconductor elements are densely formed. In the second area of the semiconductor device, semiconductor elements are sparsely formed. As described in Embodiment 1, when annealing is performed on a area (first area) in which semiconductor elements are densely formed, and another area (second area) in which semiconductor elements are sparsely formed, with flash lamp annealing light, a annealing temperature variation is caused between the first area and the second area.

According to the present embodiment, before annealing using flash lamp light is performed, a light absorbing film (or a light reflecting film) is formed on the first area and the second area. Uneven parts are formed on the surface of the light absorbing film provided on the second area at a pitch equal to or less than the central wavelength λ of flash lamp light. Thus, the ion-implantation is not performed on the second area. Consequently, the adjustment of the thermal emissivity of flash lamp light can be performed on the first area and the second area by forming the light absorbing film in such a manner. Accordingly, the annealing-temperature variation can be reduced between the first area and the second area.

Each of the above embodiments is provided for facilitating the understanding of the invention, and not intended to be interpreted to limit the invention. The invention includes equivalents thereof and can be changed/improved without departing from the scope thereof. For example, while flash lamp light is exemplified as a heat source for annealing, lasers such as an excimer laser, a yttrium aluminum garnet (YAG) laser, a carbon monoxide (CO) laser, and a carbon dioxide (CO₂) laser can be used as the heat source. Alternatively, a RTA light source, such as a halogen lamp, can be used as the heat source. A flash lamp light source using rare gas such as xenon (Xe) gas, mercury, hydrogen, or the like can be used as the light source for flash lamp light.

In addition, while the ion-implanted impurity activation heat treatment process is exemplified in the embodiments, an application of the embodiments is not limited thereto. For example, the embodiments can be applied to heat treatment processes in the formation of an insulation film, e.g., an oxidized film, or a nitride film, the improvement of a film, and increase in the diameter of each particle of an amorphous material, or a poly-silicon crystal.

1. A semiconductor device, comprising:
a first area including plural transistors formed therein; and
a second area including plural dummy transistors formed therein, the second area surrounding the first area,
wherein a pitch of the dummy transistors is equal to or less than a central wavelength of a light used to form the transistors.

2. The device of claim 1,
wherein a width of an element formation region of each dummy transistor is equal to or less than a half the pitch of the dummy transistors.

3. The device of claim 1,
wherein the pitch is a distance between edges of element isolation regions of the adjacent dummy transistors.

4. The device of claim 1,
wherein each dummy transistor includes:
an element formation region; and
an element isolation region surrounding the element formation region.

5. The device of claim 1, further comprising:
a light source configured to emit the light.

6. The device of claim 5,
wherein the light source is a flash lamp.

7. The device of claim 5,
wherein the light source is a laser.

8. A semiconductor device, comprising:
a first area provided on a semiconductor substrate, the first area including plural transistors formed therein;
a second area provided on the semiconductor substrate, the second area including plural transistors formed therein; and
an element isolation region formed to define the first area and the second area,
wherein a width of the element isolation region between the first and second areas is set to be wider than a thermal diffusion length L of a heat that is given by a light to irradiate the semiconductor substrate for forming the transistors.

9. The device of claim 8,
wherein the thermal diffusion length L is given by:
L=\sqrt{k/n/c×T}
where k is a thermal conductivity, n is a density, c is a specific heat, and T is an annealing time.

10. The device of claim 8, further comprising:
a light source configured to emit the light.

11. The device of claim 10,
wherein the light source is a flash lamp.

12. The device of claim 10,
wherein the light source is a laser.

13. A method for manufacturing a semiconductor device, the method comprising:
forming, in each of a first area and a second area of a semiconductor substrate, a gate insulating film and a gate electrode on the semiconductor substrate;
ion-implanting, in each of the first area and the second area, an impurity on a surface of the semiconductor substrate using the gate electrode as a mask;
ion-implanting, in the first area, nonconductive elements to amorphousize the gate electrode; and
irradiating, in each of the first area and the second area, the semiconductor substrate with a light to activate the impurity.

14. A method for manufacturing a semiconductor device, the method comprising:
forming, in each of a first area and a second area of a semiconductor substrate, a gate insulating film and a gate electrode on the semiconductor substrate;
ion-implanting, in each of the first area and the second area, an impurity on a surface of the semiconductor substrate using the gate electrode as a mask;
forming, in each of the first area and the second area, a light absorbing film or a light reflecting film; and
irradiating, in each of the first area and the second area, the semiconductor substrate with a light to activate the impurity,
wherein, in the second area, the light absorbing film or the light reflecting film has uneven parts on a surface thereof, and
wherein a pitch of the uneven parts is equal to or less than a central wavelength of the light.
